(19) United States
(12) Patent Application Publication
(10) Pub. No.: US 2005/0150539 A1
(43) Pub. Date: Jul. 14, 2005

(54) Monolithic thin-film thermoelectric device including complementary thermoelectric materials

(75) Inventors: Uttam Ghoshal, Austin, TX (US); Srikanth B. Samavedam, Austin, TX (US); Tat Ngai, Austin, TX (US); Andrew Carl Miner, Austin, TX (US)

Correspondence Address: ZAGORIN O'BRIEN GRAHAM LLP, 7600B N. CAPITAL OF TEXAS HWY., SUITE 350, AUSTIN, TX, 78731, US

(73) Assignee: NanoCoolers, Inc.

(21) Appl. No.: 11/020,531

(22) Filed: Dec. 23, 2004

Related U.S. Application Data
(63) Continuation-in-part of application No. 10/756,603, filed on Jan. 13, 2004.
(60) Provisional application No. 60/617,513, filed on Oct. 8, 2004.

(51) Int. Cl. H01L 35/12; H01L 35/30; H01L 37/00; H01L 35/34

(52) U.S. Cl. 136/205; 136/201

(57) ABSTRACT

A vertical, monolithic, thin-film thermoelectric device is described. Thermoelectric elements of opposing conductivity types may be coupled electrically in series and thermally in parallel by associated electrodes on a single substrate, reducing the need for mechanisms to attach multiple substrates or components. Phonon transport may be separated from electron transport in a thermoelectric element. A thermoelectric element may have a thickness less than an associated thermalization length. An insulating film between an electrode having a first temperature and an electrode having a second temperature may be a low-thermal conductivity material, a low-k, or ultra-low-k dielectric. Phonon thermal conductivity between a thermoelectric element and an electrode may be reduced without a significant reduction in electron thermal conductivity, as compared to other thermoelectric devices. A phonon conduction impeding material may be included in regions coupling an electrode to an associated thermoelectric element (e.g., a liquid metal).

### CROSS-REFERENCE TO RELATED APPLICATION(S)

This application claims the benefit under 35 U.S.C. § 119(e) of U.S. Provisional Application No. 60/617,513, filed Oct. 8, 2004, entitled “MONOLITHIC THIN-FILM THERMOELECTRIC DEVICE INCLUDING COMPLEMENTARY THERMOELECTRIC MATERIALS” by Srikanth B. Samavedam, et al., which application is hereby incorporated by reference.

This application is a continuation-in-part of co-pending application Ser. No. 10/756,603, filed Jan. 13, 2004, entitled “THERMOELECTRIC DEVICES” by Uttam Ghoshal, which application is hereby incorporated by reference.

This application is related to application Ser. No. ______ (Attorney Docket No. 089-0015), filed on even date herewith, entitled “METHOD FOR FORMING A MONOLITHIC THIN-FILM THERMOELECTRIC DEVICE INCLUDING COMPLEMENTARY THERMOELECTRIC MATERIALS” by Tat Ngai, et al.; and application Ser. No. ______ (Attorney Docket 089-0016), filed on even date herewith, entitled “APPARATUS AND METHOD FOR FORMING A THIN-FILM THEROMELECTRIC DEVICE INCLUDING A PHONON-BLOCKING THERMAL CONDUCTOR” by Srikanth B. Samavedam, et al.

### BACKGROUND

1. Field of the Invention

The present invention generally relates to thermoelectric devices.

2. Description of the Related Art

Electronic devices such as microprocessors, laser diodes, etc. generate significant amounts of heat during operation. If the heat is not dissipated, it may adversely affect the performance of these devices. Typical cooling systems for small devices are based on passive cooling methods and active cooling methods. The passive cooling methods include heat sinks and heat pipes. Such passive cooling methods may provide limited cooling capacity due to spatial limitations. Active cooling methods may include use of devices such as mechanical vapor compression refrigerators and thermoelectric coolers. Vapor compression based cooling systems generally require significant hardware such as a compressor, a condenser and an evaporator. Because of the large required volume, moving mechanical parts, poor reliability and associated cost of the hardware, use of such vapor compression based systems might not be suitable for cooling small electronic devices.

Thermoelectric cooling, for example using a Peltier device, provides a suitable cooling approach for cooling small electronic devices. A typical Peltier thermoelectric cooling device includes a semiconductor with two metal electrodes. When a voltage is applied across these electrodes, heat is absorbed at one electrode producing a cooling effect, while heat is generated at the other electrode producing a heating effect. The cooling effect of these thermoelectric Peltier devices can be utilized for providing solid-state cooling of small electronic devices.

Some typical applications of the thermoelectric cooling devices are in the field of small-scale refrigeration, e.g., small-scale refrigeration for mainframe computers, thermal management integrated circuits, magnetic read/write heads, optical and laser devices, and automobile refrigeration systems. However, unlike conventional vapor compression-based cooling systems, thermoelectric devices have no moving parts. The lack of moving parts increases reliability and reduces maintenance of thermoelectric cooling devices as compared to conventional cooling systems. Thermoelectric devices may be manufactured in small sizes making them attractive for small-scale applications. In addition, the absence of refrigerants in thermoelectric devices has environmental and safety benefits. Thermoelectric coolers may be operated in a vacuum and/or weightless environments and may be oriented in different directions without effecting performance.

However, typical thermoelectric devices are limited by low efficiency as compared to conventional cooling systems. In general, the efficiency of a thermoelectric device depends on material properties and is quantified by a figure of merit (ZT):
ZT=S² Tσ/λ,
where S is the Seebeck coefficient, which is a property of a material, T is the average temperature of the thermoelectric material, σ is the electrical conductivity of the thermoelectric material, and λ is the thermal conductivity of the thermoelectric material. Typical thermoelectric devices have a thermoelectric figure of merit less than 1. In comparison, a thermoelectric device that is as efficient as a conventional vapor compression refrigerator would have a figure of merit of approximately 3.

Referring to the above relationship for the figure of merit, a thermoelectric device utilizing a material having high electrical conductivity and low thermal conductivity generally has a high figure of merit. This requires reduction in thermal conductivity without a significant reduction in electrical conductivity. Various approaches have been proposed to increase the figure of merit of thermoelectric devices by decreasing the thermal conductivity of the material while retaining high electrical conductivity.

Superlattices grown on lattice-matched substrates are periodic structures generally consisting of several to hundreds of alternating thin-film layers of semiconductor material where each layer is typically between 10 and 500 Angstroms thick having reduced thermal conductivity. Typical superlattices of materials such as Bi₂Te₃ and Sb₂Te₃ are grown on GaAs and BaF₂ wafers in such a way as to disrupt thermal transport while enhancing the electronic transport in the direction perpendicular to the superlattice interfaces. However, superlattices are typically grown on semiconductor wafers and then transferred to a metal surface, which may be difficult to achieve.

The thermal conductivity of a material may also be reduced using quantum dots (i.e., a structure where charge carriers are confined in all three spatial dimensions) and nanowires (i.e., an ultrafine tube of a semiconductor material). Quantum confinement of carriers in reduced dimensional structures results in larger Seebeck coefficients and hence a better thermoelectric figure of merit.

Cold points may also be used to increase the figure of merit of thermoelectric devices. A cold point is a sharp point contact between a hot electrode and a cold electrode of a thermoelectric device. The cold points have a high ratio of electrical conductivity to thermal conductivity at the contact, which may improve the figure of merit of the thermoelectric device. Figures-of-merit in the range of 1.3 to 1.6 can be achieved using these thermoelectric devices. However, typical manufacturing processes of the cold points require precise lithographic and mechanical alignments. The tolerances of the manufacturing process for these alignments often result in degraded performance because it is difficult to maintain uniformity in radii and heights of the cold points. In practice, it may be difficult to achieve nanometer level planarity resulting in point intrusions or absence of contact. These current crowding effects increase the current flowing through point intrusions and decrease the current in points making poor contact. In addition, structured cold point devices achieve only localized cooling in a small area near each cold point. The actual area of cooling (i.e. the area around the cold points between the cold electrode and the hot electrode) is small compared to the total area to be cooled in the device. The small cooling areas result in large thermal parasitics and poor efficiency.

Accordingly, improved thermoelectric cooling devices and improved techniques for providing these devices are desired.

### SUMMARY

In some embodiments, the present invention provides a vertical, monolithic, thin-film thermoelectric device. A thermoelectric device consistent with the present invention may include thermoelectric elements of opposing conductivity types coupled electrically in series and thermally in parallel by associated electrodes on a single substrate, reducing the need for solder joints or other structures or mechanisms to attach multiple substrates, components, or assemblies together. In operation, a vertical thermoelectric device consistent with the present invention includes contacts on the front side having a temperature (e.g., T_{HOT}) substantially different from a temperature (e.g., T_{COLD}) of a contact thermally coupled to the backside of the substrate. The invention is also contemplated to provide methods for forming and utilizing such structures.

In some embodiments of the present invention, phonon transport is separated from electron transport in a thermoelectric element of a thermoelectric device. A thermoelectric element may have a thickness less than a thermalization length associated with the thermoelectric material. A thermoelectric element may include thin-film or ultra-thin-film thermoelectric materials. A thermoelectric material included in the thermoelectric device may have a figure of merit greater than approximately one. Thermoelectric elements of opposing conductivity types may be formed by a coarse patterning step followed by a fine patterning step. A thermoelectric material may be selectively converted to a thermoelectric material of an opposing conductivity type to form thermoelectric elements of opposing conductivity types.

In some embodiments of the present invention, a thermoelectric device includes an insulating film between an electrode having a first temperature and an electrode having a second temperature, the second temperature being substantially different than the first temperature. The insulating film may be a low-thermal conductivity material (e.g., parylene, an aerogel, etc.), a low-k dielectric, an ultra-low-k dielectric, or other suitable material. The insulating film may be formed by sacrificial techniques.

In some embodiments of the present invention, phonon thermal conductivity between a thermoelectric element and an electrode in a thermoelectric device is reduced without a significant reduction in electron thermal conductivity, as compared to other thermoelectric devices. A phonon conduction impeding material may be included in regions coupling an electrode to an associated thermoelectric element. The phonon conduction impeding material may include a liquid metal.

The foregoing is a summary and thus contains, by necessity, simplifications, generalizations and omissions of detail. Consequently, those skilled in the art will appreciate that the foregoing summary is illustrative only and that it is not intended to be in any way limiting of the invention. The inventive concepts described herein are contemplated to be used alone or in various combinations. Other aspects, inventive features, and advantages of the present invention, as defined solely by the claims, may be apparent from the detailed description set forth below.

### BRIEF DESCRIPTION OF THE DRAWINGS

The present invention may be better understood, and its numerous objects, features, and advantages made apparent to those skilled in the art by referencing the accompanying drawings.

FIG. 1 illustrates a cross-sectional view of a vertical thermoelectric device in accordance with some embodiments of the present invention.

FIG. 2A illustrates a cross-sectional view of a thermoelectric element in accordance with some embodiments of the present invention.

FIG. 2B illustrates the variation of electron and phonon temperatures within a thermoelectric element.

FIGS. 3-10 illustrate cross-sectional views of a vertical thermoelectric device in progressive stages of manufacture consistent with some embodiments of the present invention, in particular:

FIG. 3 illustrates a cross-sectional view of a substrate including a conductive structure inlaid in a dielectric layer consistent with some embodiments of the present invention.

FIG. 4 illustrates a cross-sectional view of the substrate including patterned conductive structures consistent with some embodiments of the present invention.

FIG. 5A illustrates a cross-sectional view of the substrate including a thermoelectric element of a first type consistent with some embodiments of the present invention.

FIG. 5B illustrates a cross-sectional view of the substrate including a mask on the thermoelectric element of a first type consistent with some embodiments of the present invention.

FIG. 6A illustrates a cross-sectional view of the substrate including a thermoelectric material of a first type consistent with some embodiments of the present invention.

FIG. 6B illustrates a cross-sectional view of the substrate including a mask on a portion of the thermoelectric material of a first type consistent with some embodiments of the present invention.

FIG. 6C illustrates a cross-sectional view of the substrate including a thermoelectric material of a second type consistent with some embodiments of the present invention.

FIG. 7 illustrates a cross-sectional view of the substrate including a thermoelectric element of a first type and a thermoelectric element of a second type consistent with some embodiments of the present invention.

FIG. 8 illustrates a cross-sectional view of the substrate including a phonon conduction impeding material on the thermoelectric element of a first type and the thermoelectric element of a second type consistent with some embodiments of the present invention.

FIG. 9 illustrates a cross-sectional view of the substrate including an insulating layer consistent with some embodiments of the present invention.

FIG. 10 illustrates a cross-sectional view of the substrate including contacts consistent with some embodiments of the present invention.

FIGS. 11-20 illustrate methods of fabricating a vertical thermoelectric device consistent with some embodiments of the present invention.

FIG. 11 illustrates a cross-sectional view of a substrate including a dielectric layer and conductive layers consistent with some embodiments of the present invention.

FIG. 12 illustrates a cross-sectional view of the substrate including a patterned photoresist and conductor structure consistent with some embodiments of the present invention.

FIG. 13 illustrates a cross-sectional view of the substrate including a thermoelectric layer of a first type and a conductive layer on the thermoelectric layer of a first type consistent with some embodiments of the present invention.

FIG. 14 illustrates a cross-sectional view of the substrate including a coarsely patterned thermoelectric structure of a first type consistent with some embodiments of the present invention.

FIG. 15 illustrates a cross-sectional view of the substrate including a thermoelectric material of a second type and a conductive layer on the thermoelectric material of a second type consistent with some embodiments of the present invention.

FIG. 16 illustrates a cross-sectional view of the substrate including a finely patterned thermoelectric structure of a second type consistent with some embodiments of the present invention.

FIG. 17 illustrates a cross-sectional view of the substrate including a finely patterned thermoelectric structure of a first type consistent with some embodiments of the present invention.

FIG. 18 illustrates a cross-sectional view of the substrate including a dielectric layer consistent with some embodiments of the present invention.

FIG. 19 illustrates a cross-sectional view of the substrate including contact holes consistent with some embodiments of the present invention.

FIG. 20 illustrates a cross-sectional view of the substrate including contacts consistent with some embodiments of the present invention.

FIG. 21 illustrates a top-down view of a thermoelectric device consistent with some embodiments of the present invention.

FIG. 22 illustrates an exemplary application of a thermoelectric device consistent with some embodiments of the present invention.

The use of the same reference symbols in different drawings indicates similar or identical items.

### DETAILED DESCRIPTION

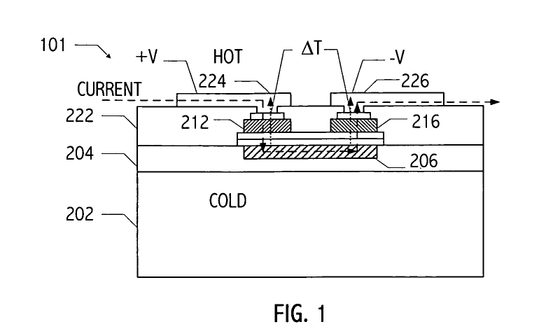

An exemplary thermoelectric device (thermoelectric device 101 of FIG. 1) includes contacts on a front side (i.e., “top” side) of the structure (e.g., contacts 224 and 226) and a contact thermally coupled to a backside of the structure (e.g. contact 206). As used herein, a contact thermally “coupled” to a backside of the structure may be directly or indirectly coupled to the backside of the structure. In operation, the contacts on the front side of the thermoelectric device have a temperature (e.g., T_{HOT}) substantially different from a temperature (e.g., T_{COLD}) of the contact thermally coupled to the backside of the substrate. The vertical thermoelectric device includes an n-type thermoelectric element and a p-type thermoelectric element (e.g., thermoelectric elements 212, and 216) coupled electrically in series and thermally in parallel. For example, in operation of thermoelectric device 101, a voltage differential is applied between contacts 224 and 226 creating a Peltier effect transferring thermal energy vertically away from contact 206 towards contacts 224 and 226.

A thermoelectric device with a figure-of-merit greater than one may be achieved by reducing the thermal conductivity component (λ) of the figure of merit (i.e., ZT=S² Tσ/λ) for the thermoelectric device, as compared to other thermoelectric devices, without significantly reducing the electrical conductivity. The thermal conductivity of the thermoelectric device (λ) includes two components, i.e., the thermal conductivity due to electrons (referred to as electron thermal conductivity, λₑ, hereinafter) and the thermal conductivity due to phonons (referred to as phonon thermal conductivity, λₚ, hereinafter). A phonon is a vibrational wave in a solid that may be viewed as a particle having energy and a wave length. Phonons carry heat and sound through the solid, moving at the speed of sound in the solid. Thus, λ=λₑ+λₚ. Typically, λₚ forms the dominant component of λ. The value of λ may be reduced by reducing the value of either λₑ or λₚ. A reduction in λₑ reduces electrical conductivity σ; thereby producing an overall reduction in the figure of merit, ZT. However, a reduction in λₚ without significantly affecting λₑ may reduce the value of λ without affecting σ and may produce a corresponding increase of the figure of merit.

The reduction of phonon thermal conductivity λₚ may be accomplished by decoupling and separating the phonon conduction from the electron conduction by the use of ultra-thin-film semiconductor thermoelectric elements and by selectively attenuating phonon conduction using a phonon conduction impeding structure, without significantly affecting the electron conduction. The use of a phonon conduction impeding materials and ultra-thin thermoelectric films in thermoelectric device 101 reduce the value of λₚ, thereby reducing the value of λ and increasing the figure of merit.

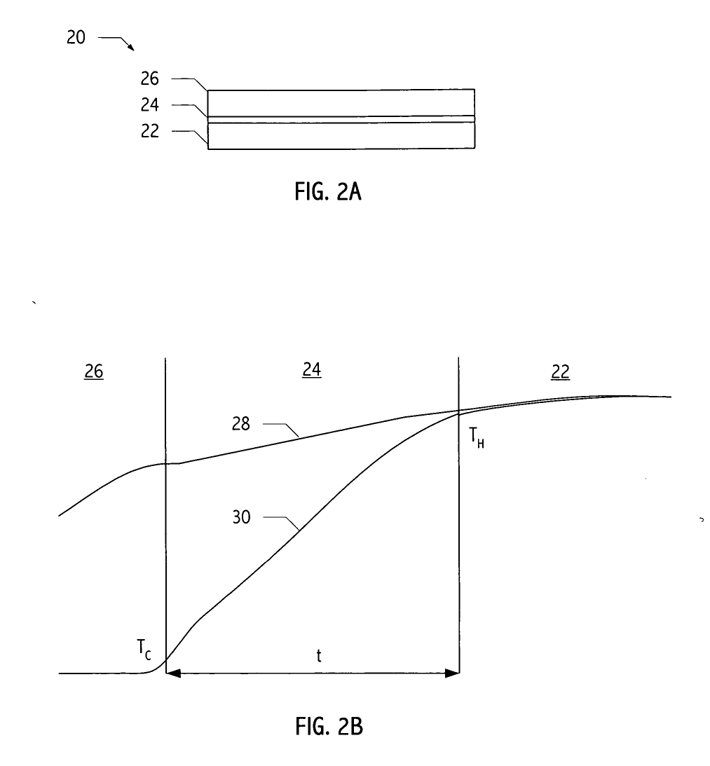

For example, thermoelectric device 20 of FIG. 2A includes thermoelectric element 24 having a thickness t. An electrical potential is applied across thermoelectric element 24 such that the electric current flows from electrode 22 to electrode 26 and electrons flow in the opposite direction. Once injected into thermoelectric element 24 from electrode 26, the electrons are not in a thermal equilibrium with the phonons in thermoelectric element 24 for a finite distance Λ from the surface of contact between electrode 26 and thermoelectric element 24. This finite distance Λ is known as thermalization length. The thermalization length is the distance traveled by electrons after which thermal equilibrium between electrons and phonons occurs. For example, when a material is heated, the electrons start moving to conduct the thermal energy, collide with phonons, and share their energy with the phonons. As a result, the temperature of phonons increases until a thermal equilibrium between the electrons and the phonons is achieved. In some embodiments of the invention, the thickness t of thermoelectric elements is less than the distance Λ. Hence, the electrons and phonons are not in a thermal equilibrium in thermoelectric element 24 and do not affect each other in the energy transport.

Once the phonon transport process and the electron transport process are separated, the difference in the thermal conduction mechanisms in materials having a low acoustic velocity (i.e., phonon conduction impeding materials) and other materials may be exploited. Thermal conduction in metals (liquid as well as solid) is due to the transport of electrons and phonons. Electrode 26 may include a phonon conduction impeding medium (i.e., a material having a low acoustic velocity) having a high electron conductivity. Phonon conduction impeding materials include (without limitation) liquid metals, interfaces created by cesium doping, and solid metals such as indium, lead and thallium that have very low acoustic velocities, i.e., acoustic velocities less than 1200 m/s. The net effect is that phonon thermal conductivity between the electrodes of the thermoelectric cooler is significantly reduced, i.e., λₚ<0.5 W/m-K, without reducing electrical conductivity.

As used herein, “liquid metal” refers to metals that are in a liquid state during at least a portion of operating temperature for a device or other temperature of interest. Examples of liquid metals include at least gallium and gallium alloys. Liquid metals or liquid metal alloys generally have less of ionic order and crystal structure than solid metals. This results in lower acoustic velocities and negligible phonon thermal conductivity λₚ in the liquid metals as compared to phonon thermal conductivity of solid metals. The phonon thermal conductivity of the liquid metals is less than the phonon conductivity of typical solid-phase glasses or polymers with thermal conductivity values less than 0.1 W/m-K. As a result, the thermal conductivity in liquid metals is predominantly due to electrons. However, the electronic conduction is not similarly impeded because the phonon conduction impeding medium has a high electronic conductivity and the electrons can tunnel through the interface barriers with minimal resistance. In other words, the electronic conduction is effectively decoupled or separated from the phonon-conduction.

Notwithstanding the type of material used for electrode 26, mismatches of acoustic velocities in the thermoelectric material 24 and electrode 26 introduce interface thermal resistances such as Kapitza thermal boundary resistances. The associated reduction of phonon thermal conductivity λₚ (in some cases to negligible amounts) reduces the thermal conductivity in thermoelectric device 20. In some devices in accordance with the present invention, the thermal conductivity may be predominantly due to electron thermal conductivity λₑ, i.e., λ→λₑ. The reduction in thermal conductivity contributes to an improved figure of merit.

FIG. 2B illustrates the variation of electron and phonon temperatures within exemplary thermoelectric device 20. The temperature of electrode 26 is T_{C} and the temperature of electrode 22 is T_{H}. The temperature of electrons in electrode 26 is approximately T_{C}, while the temperature of electrons in electrode 22 is approximately T_{H}. The variation of temperature of electrons in thermoelectric element 24 (i.e., temperature 30) is nonlinear and is governed by heat conduction equations. The temperature of phonons in electrode 22 is approximately equal to T_{H} because of the electron-phonon coupling within the solid. However, in electrode 26 (i.e., the electrode including a phonon conduction impeding material), the temperature of phonons in the thermoelectric layer at the thermoelectric element interface is not equal to the electrode temperature because of the thermal impedance of the phonons at the interface. The temperature of the phonons in thermoelectric element 24 (i.e., temperature 28) varies between the temperature of electrode 22, i.e., T_{H}, and the temperature of phonons in electrode 26, as shown in FIG. 2B. The electron and the phonon temperatures in thermoelectric element 24 are not in equilibrium.

One-dimensional coupled equations describing the heat transfer for the electron-phonon system within the thermoelectric element (e.g., thermoelectric element 24), derived using the Kelvin relationship, the charge conservation equation, and the energy conservation equation are:
−∇·(λₑ∇Tₑ)−|\overline{J}|²/σ+P(Tₑ−Tₚ)=0
−∇·(λₚ∇Tₚ)−P(Tₑ−Tₚ)=0 where,
Tₑ is the temperature of the electrons,
Tₚ is the temperature of the phonons,
λₑ is the electrical conductivity of the thermoelectric element,
J is the local current density,
σ is the electrical conductivity of the thermoelectric element,
λₚ is the lattice thermal conductivity of the thermoelectric element, and
P is a parameter that represents the intensity of the electron-phonon interaction.

The parameter P may be given for three-dimensional isotropic conduction as:
P=(3Ξ² m*² k_{B} nk_{F})/(πρ [symbol] ³), where
Ξ is the deformation interaction,
m* is the effective electron mass,
k_{B} is the Boltzmann's constant,
n is the electron density,
k_{F} is the Fermi wavevector,
ρ is the density of the thermoelectric element, and
[symbol] is the reduced Planck's constant.

Additional information may be obtained from “Semiconductors” (31, 265 (1997)) by V. Zakordonets and G. Loginov; “Boundary Effects in Thin film Thermoelectrics” by M. Bartkowiak and G. Mahan, Materials Research Society Symposium Proceedings, Vol. 545, 265 (1999); and “Electrons and Phonons in Semiconductor Multi-layers”, by B. K. Ridley (Cambridge University Press, 1997, Chapter 11.7).

These one-dimensional coupled equations may be solved subject to boundary conditions. The injected electrons in the thermoelectric element at the boundary x=0 have a temperature approximately equal to the temperature of electrode 26, i.e., Tₑ(0)=T_{C}. Similarly, the temperature of electrons at the other boundary of the thermoelectric element is approximately equal to the temperature of electrode 22. The phonons are also at approximately the same temperature as that of electrode 22, i.e., Tₑ(t)=Tₚ(t)=T_{H}.

Assuming a negligible gradient for the phonon temperature across the boundary of the electrode 22 and thermoelectric element 24, i.e.,

$$\frac{ⅆ {T}_{p}}{ⅆ x} {\vert}_{x = 0} = 0 ,$$

the one-dimensional coupled equations may be solved to determine heat flux q₀ as a function of the temperatures at the surfaces of thermoelectric element 24.

$${q}_{0} = - \frac{{\vert \overline{J} \vert}^{2} t ξ}{2 σ} - {λ}_{eff} \frac{( {T}_{H} - {T}_{C} )}{t} where ,$$

ξ is the factor for reduction in Joule heat backflow, and λ_{eff} is the effective electrical conductivity of the thermoelectric element.

The net cooling flux J_{q} at electrode 26, including the Seebeck cooling effect is J_{q}=ST_{c}|J|+q₀. The effective thermal conductivity for the thermoelectric element 24 is:

$${λ}_{eff} = \frac{{λ}_{e} ( {λ}_{e} + {λ}_{p} )}{{λ}_{e} + {λ}_{p} [ \frac{tanh ( t / Λ )}{( t / Λ )} ]} .$$

As t/Λ→0, λ→λₑ, the thermal conductivity is reduced to approximately the electronic thermal conductivity. The characteristic thermalization length Λ is approximately 500 nanometers for Bi_{0.5}Sb_{1.5}Te₃ and Bi₂Te_{2.8}Se_{0.2} chalcogenides. The thermoelectric devices with film thickness of t˜100 nanometers thus have t/Λ of around 0.2 and the thermal conductivity for the thermoelectric element is approximately equal to the electronic thermal conductivity. Hence, the thermoelectric devices operate in the phonon-glass-electron-crystal (PGEC) limit at the limiting value for the figure-of-merit. The figure-of-merit for the thin-film thermoelectric structure is:
ZT=S² Tσ/λₑ.

According to the Wiedemann-Franz law the electronic thermal conductivity is related to the electrical conductivity by the by the relation λₑ=L₀σT. Thus, ZT=S²/L₀, where L₀ is the Lorenz number for the thermoelectric element. For pure metals, L₀=(λ²/3)(k/e)². For Bi_{0.5}Sb_{1.5}Te₃, \sqrt{L₀}˜125 μV/Kelvin. The first term in the formula for qₒ,

$$i . e . \frac{{\vert \overline{J} \vert}^{2} t ξ}{2 σ} ,$$

depicts the backflow of Joule heat to the cold electrode. In conventional devices, half of the Joule heat developed in the thermoelectric element flows back to the cold electrode. However, in a thermoelectric device in accordance with the present invention, this backflow is reduced by a factor of ξ. The factor for reduction in Joule heat backflow ξ is given by:

$$ξ = \frac{{λ}_{e} + {λ}_{p} [ \frac{1 - sech ( t / Λ )}{{( t / Λ )}^{2}} ]}{{λ}_{e} + {λ}_{p} [ \frac{tanh ( t / Λ )}{( t / Λ )} ]}$$

The reduction of backflow of Joule heat allows for higher efficiency operation at larger temperature differentials. Also, the minimum cold end temperature for the thermoelectric device may be derived to be:

$${T}_{c min} = {T}_{h} / \sqrt{1 + \frac{{S}^{2} σ}{ξ {L}_{0}}} \leq {T}_{h} / \sqrt{1 + \frac{{S}^{2}}{{L}_{0}}} .$$

The maximum coefficient of performance (COP), η, i.e. the ratio of the cooling power at the cold electrode to the total electrical power consumed by the cooler is given by the relation:

$$η = ( \frac{\sqrt{1 + {S}^{2} / {L}_{0}} - 1}{\sqrt{1 + {S}^{2} / {L}_{0}} + 1} ) \frac{{T}_{C}}{{T}_{H} - {T}_{C}} .$$

The thermodynamic efficiency ε is the ratio of the COP of the thermoelectric device to that of an ideal Carnot refrigerator operating between the same temperatures (T_{H} and T_{C}),

$$ɛ = ( \frac{\sqrt{1 + {S}^{2} / {L}_{0}} - 1}{\sqrt{1 + {S}^{2} / {L}_{0}} + 1} )$$

In the case of thermoelectric devices based on Bi_{0.5}Sb_{1.5}Te₃ or Bi₂Te₃ materials, S˜220 μV/Kelvin and hence ε˜0.3. It may be seen that the thermodynamic efficiency of a thermoelectric device in accordance with the present invention is competitive with mechanical vapor compression refrigerators.

A metal to n-type semiconductor junction produces a temperature difference opposite to a metal to p-type semiconductor junction for the same direction of current flow. A typical thermoelectric device design applies this characteristic by including an n-type semiconductor thermoelectric element coupled electrically in series and thermally in parallel to a p-type semiconductor thermoelectric element. A process for manufacturing such thermoelectric devices may include manufacturing thermoelectric elements of different types on separate substrates or manufacturing thermoelectric elements on one substrate, but forming associated electrodes on separate substrates. Manufacturing separate substrates may increase complexity and cost of forming usable thermoelectric device configurations. Integrating separate substrates to form thermoelectric devices configured in usable configurations may include soldering the substrates together. Solder joints are typically susceptible to swelling and failure, and may be detrimental to the reliability of thermoelectric devices including multiple substrates.

A thin film process may be used to produce monolithic (i.e., integrated on a single substrate) thermoelectric devices including thermoelectric elements of a first and a second conductivity type thermally and electrically coupled to associated electrodes on a single substrate, reducing the need for solder joints or other structures or mechanisms to attach multiple substrates, components, or assemblies together. In general, thin-film (i.e., on the order of 1 μm thick, e.g., approximately 5 μm-20 μm) and ultra-thin-film (i.e., less than approximately 1 μm, e.g., 0.1 μm-0.5 μm thick) thermoelectric layers are less susceptible to cracking than thick (i.e., greater than approximately 20 μm thick) thermoelectric films and further improve manufacturability of thermoelectric devices.

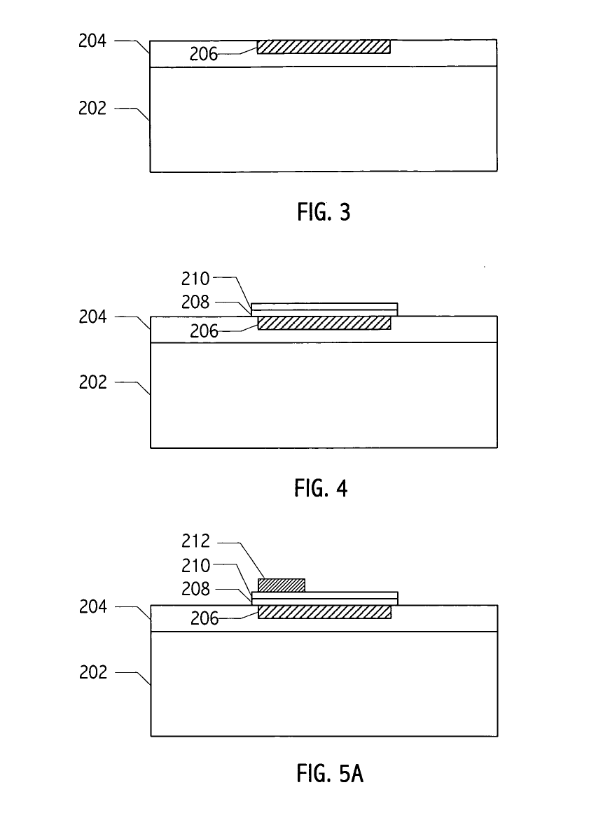

A vertical thermoelectric device, as referred to herein, is a thermoelectric device including a thermal contact on a front side of the thermoelectric device having a temperature (e.g., T_{HOT}) substantially different from a temperature (e.g., T_{COLD}) of a thermal contact on a backside of the thermoelectric device. Cross-sectional views of a vertical thermoelectric device in progressive stages of manufacture consistent with some embodiments of the present invention are illustrated in FIGS. 3-10.

Referring to FIG. 3, a substrate (e.g., substrate 202) may be silicon, gallium arsenide, indium phosphide, thermally-conducting polished ceramic substrates, polished metal, or other suitable materials. A dielectric layer, e.g., dielectric layer 204, is formed on substrate 202. The dielectric layer may be thermal oxide, CVD tetra-ethyl-ortho-silicate (TEOS) oxide, PECVD oxide, spin-on-glass, or other suitable material. In an exemplary embodiment of the invention, dielectric layer 204 is 0.5 μm thick. As used herein, a dielectric layer “formed on” a substrate may include intervening structures or the dielectric layer may be formed directly on the substrate. Dielectric layer 204 may be patterned using contact lithography, UV stepper, e-beam, or other suitable technique, and etched by plasma etch, wet etch, or other suitable technique, to form a well in which conductive link 206 is formed. In one embodiment of the invention, conductive link 206 is formed from copper. A copper seed may be formed by TaN/Ta/Cu self-ionized plasma (SIP) physical vapor deposition (PVD), TaN atomic layer deposition (ALD) barrier and Cu SIP PVD, or by other suitable technique. The copper seed may then be electroplated and followed by chemical mechanical planarization (CMP) to planarize conductive link 206 with dielectric layer 204. Conductive link 206 may also be formed from aluminum, or other suitable material.

A patterned conductive structure is formed from conductive link 206 and patterned conductive layers 208 and 210, as illustrated in FIG. 4. Conductive layer 210 may be formed from platinum, to prevent electromigration at high current densities and form a good interface between a conductive material and a semiconducting thermoelectric material. However, platinum may not adhere well to some oxides or metals. Thus, in some embodiments of the invention, conductive layer 208 is included to improve adhesion of conductive layer 210 to conductive link 206. Conductive layer 208 may be formed by an ultra-thin (e.g., 10-30 nm) layer of titanium-tungsten (TiW). Conductive layers 208 and 210 may be formed by PVD, CVD, e-beam evaporation, or other suitable technique, followed by metal patterning (e.g., contact lithography, UV stepper, e-beam, or other suitable technique), mask, and a metal etch (plasma etch, wet etch, or other suitable technique). The structure formed by conductive layers 208 and 210, which may be approximately 200-400 Å thick, may also be formed by other conductive materials, e.g., Ni, and may not include a separate layer to prevent diffusion.

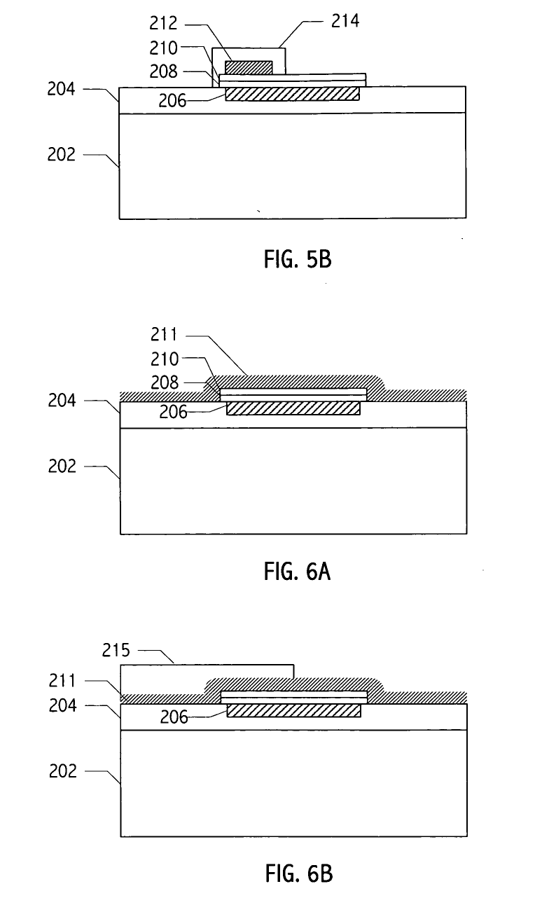

Referring to FIG. 5A, a thermoelectric element (e.g., p-type thermoelectric element 212) is formed on substrate 202. Thermoelectric element 212 may be thin or ultra-thin, and in one embodiment of the present invention, thermoelectric element 212 is approximately 0.1 μm thick. Thermoelectric element 212 may be formed from any of a variety of thermoelectric materials and corresponding techniques for forming thermoelectric materials. For example, thermoelectric element 212 may be formed using physical vapor deposition (PVD), electro-deposition, metallo-organic chemical vapor deposition (MOCVD), molecular beam epitaxy (MBE), or other suitable technique. In some embodiments of the present invention, thermoelectric element 212 has a high power factor (S²σ) and a thickness less than its characteristic thermalization length, as discussed above. Exemplary thermoelectric semiconductor materials include p-type Bi_{0.5}Sb_{1.5}Te₃, n-type Bi₂Te_{2.8}Se_{0.2}, n-type Bi₂Te_{3.2}, superlattices of constituent compounds such as Bi₂Te₃/Sb₂Te₃ superlattices, lead chacogenides such as PbTe or skutteridites such as CoSb₃, traditional alloy semiconductors SiGe, BiSb alloys, or other suitable thermoelectric materials. The choice of material may depend upon the temperatures at which the thermoelectric device is intended to operate.

In some embodiments of the invention, the thermoelectric material is patterned by typical semiconductor patterning techniques (e.g., forming a layer of photoresist on the substrate, selectively exposing the photoresist to define areas to be etched, and selectively etching areas of photoresist based upon those areas selectively exposed, and then etching the underlying and now exposed material layer) to form thermoelectric element 212. A patterned, hard mask, e.g., mask 214 in FIG. 5B, may be formed on thermoelectric element 212 (e.g., by patterning PECVD oxide, spin-on-glass, or other suitable material) to protect thermoelectric element 212 from effects of subsequent processing.

Referring to FIG. 7, a thermoelectric element, e.g., n-type thermoelectric element 216, is formed on substrate 202. Thermoelectric element 216 may be thin or ultra-thin, and in one embodiment of the present invention, thermoelectric element 216 is approximately 0.1 μm thick. Thermoelectric element 216 may be formed from any of the thermoelectric materials and corresponding techniques for forming thermoelectric materials described above. The thermoelectric material may be patterned by typical semiconductor patterning techniques to form thermoelectric element 216. Following the formation of thermoelectric element 216, mask 214 is removed, e.g., by wet etch, plasma etch, or other suitable technique. Note that the order of forming the n-type thermoelectric element and the p-type thermoelectric element may be reversed.

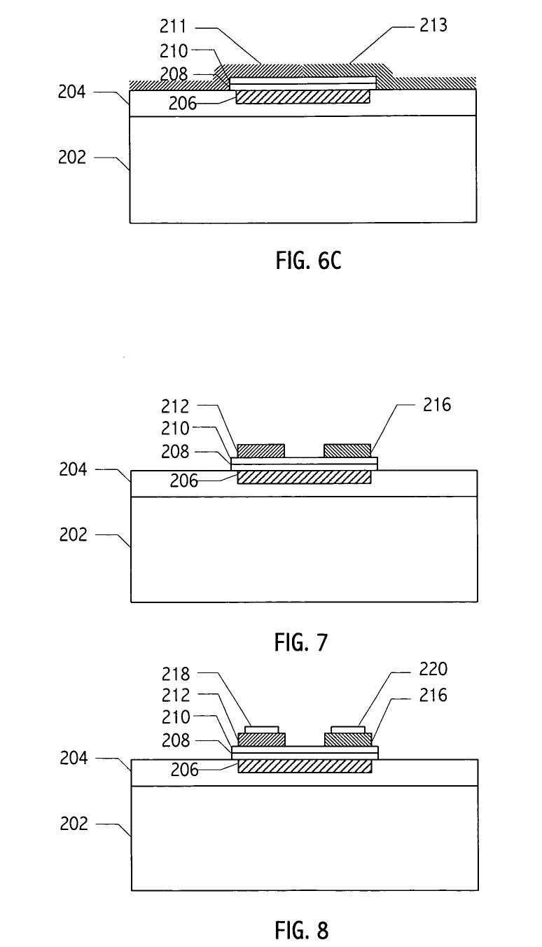

In some embodiments of the present invention, thermoelectric elements are formed by a technique illustrated in FIG. 6A-6C. The p-type thermoelectric material e.g., thermoelectric material 211, is formed on the substrate (FIG. 6A). Thermoelectric material 211 may be thin or ultra-thin, and in one embodiment of the present invention, thermoelectric material 211 is approximately 0.1 μm thick. Thermoelectric material 211 may be formed from any of the thermoelectric materials and corresponding techniques for forming thermoelectric materials described above. A hard mask, e.g., mask 215, is formed on thermoelectric material 211. Mask 215 may be PECVD oxide, spin-on-glass, or other suitable material formed by a suitable technique. Mask 215 is patterned to expose a portion of thermoelectric material 211. The exposed portion of thermoelectric material 211 is converted from p-type to n-type (or from n-type to p-type, as the case may be). The conversion technique may include annealing thermoelectric material 211, implanting a material with high concentrations of majority carriers of a second type, diffusion from a thin-film formed on thermoelectric material 211, reaction with a thin-film formed on thermoelectric material 211, or other suitable technique. Mask 215 is then removed by wet etch, plasma etch, or other suitable technique, to expose thermoelectric material 211 and thermoelectric material 213, as illustrated in FIG. 6C. Thermoelectric material 211 and thermoelectric material 213 may be then patterned using a photolithography step and an etch step to form thermoelectric elements 212 and 216, as illustrated in FIG. 7. Typical thermoelectric elements may be approximately 3-81 μm wide. Note that the order of forming the n-type thermoelectric element and the p-type thermoelectric element may be reversed.

Electrodes electrically and thermally coupled to thermoelectric elements 212 and 216 are formed on the structure. These electrodes may include a phonon conduction impeding material, i.e., a material with reduced ionic order and crystal structure, resulting in negligible phonon conduction of the material, as discussed above. A phonon conduction impeding material is formed on the substrate by PVD, e-beam evaporation, CVD, or other suitable technique. Phonon conduction impeding materials include most liquids, including liquid metals, some metallic solids, e.g., indium, lead, lead-indium, and thallium, and solid-solid interfaces with cesium doping. The phonon conduction impeding material may include gallium, indium, lead, tin, lead-indium, lead-indium-tin, gallium-indium, gallium-indium-tin, gallium-indium with cesium doping at the surface. In one embodiment of the invention, the phonon conduction impeding material includes 65 to 75% by mass gallium and 20 to 25% indium. Materials such as tin, copper, zinc and bismuth may also be present in small percentages. An exemplary material includes 66% gallium, 20% indium, 11% tin, 1% copper, 1% zinc and 1% bismuth. Other exemplary materials include mercury, bismuth-tin alloy (e.g., 58% bismuth, 42% tin by mass), and bismuth-lead alloy (e.g., 55% bismuth, 45% lead).

In general, the electrical connection between a liquid metal and a thermoelectric element is established mainly by electron tunneling across a sub-nanometer tunneling barrier at the interface between the liquid metal and the thermoelectric element. This tunneling barrier is formed due to non-adherence of molecules of the liquid metal with the molecules of the thermoelectric element. The electrical conduction properties of the tunneling gap are dependent on the atomic gaps, which in turn are dependent on the wetting and surface tension properties of the liquid metal. Junctions with small tunneling gaps approach near-ideal electrical conduction. A liquid metal may also be used with cesium vapor doping at the interface of the liquid metal and the thermoelectric element to further reduce the value of phonon thermal conductivity. Droplets of liquid metal may be formed by micropipette dispensing techniques, pressure fill techniques, jet printing or by sputtering methods. When using a liquid metal, physical barriers (e.g., barriers formed from a dielectric material) may be used to contain the liquid metal.

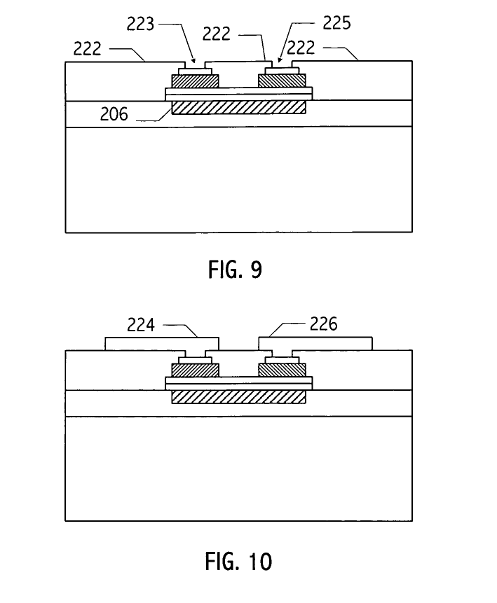

In one embodiment of the invention, the phonon conduction impeding material, e.g., indium, is in-situ capped by a layer of TiW. The phonon conduction impeding material may be patterned using contact lithography, UV stepper, e-beam, or other suitable techniques. An indium etch mask is followed by a plasma etch, wet etch, or other suitable technique for etching TiW/In to form phonon conduction impeding elements 218 and 220 of FIG. 8. Referring to FIG. 9, insulator 222 is formed on the substrate using PECVD oxide, spin-on-glass, or other suitable technique. Contact holes 223 and 225 are formed in insulator 222 by a plasma etch, wet etch, or other suitable technique. Contacts 224 and 226 are typically formed from aluminum, copper, or other suitable conducting material (FIG. 10). The conducting material is formed on the substrate (e.g., using PVD, CVD, evaporation, or other suitable technique), patterned, and etched (e.g., using wet etch, plasma etch, or other suitable technique) to form contacts 224 and 226. Contacts 224 and 226 are thermally insulated from conductive link 206.

Referring back to FIG. 9, in some embodiments of the present invention, insulator 222 is a low-k dielectric layer (i.e., a material layer having a dielectric constant lower than, e.g., 3.9, the dielectric constant of thermally grown SiO₂), an ultra-low-k dielectric layer (i.e., a material layer having a dielectric constant lower than approximately 2.0), or a low thermal conductivity layer (i.e., a material layer having thermal conductivity of approximately 0.1 W/m-K or below, e.g., parylene). In some embodiments of the present invention, sacrificial techniques may be used to form insulator 222. For example, a sacrificial layer (e.g., SiO₂, a low-k dielectric layer, or other suitable material layer) may be formed on the substrate and patterned to form contact holes 223 and 225 by any of the techniques described above. After contacts 224 and 226 are formed, the sacrificial layer is removed (e.g., etched away) and a layer having an ultra-low dielectric constant and/or a low thermal conductivity is formed. In some embodiments of the present invention, insulator 222 is an aerogel. At standard temperature and pressure, some varieties of aerogels have a thermal conductivity less than 0.005 W/m-K, whereas air has a thermal conductivity of 0.026 W/m-K.

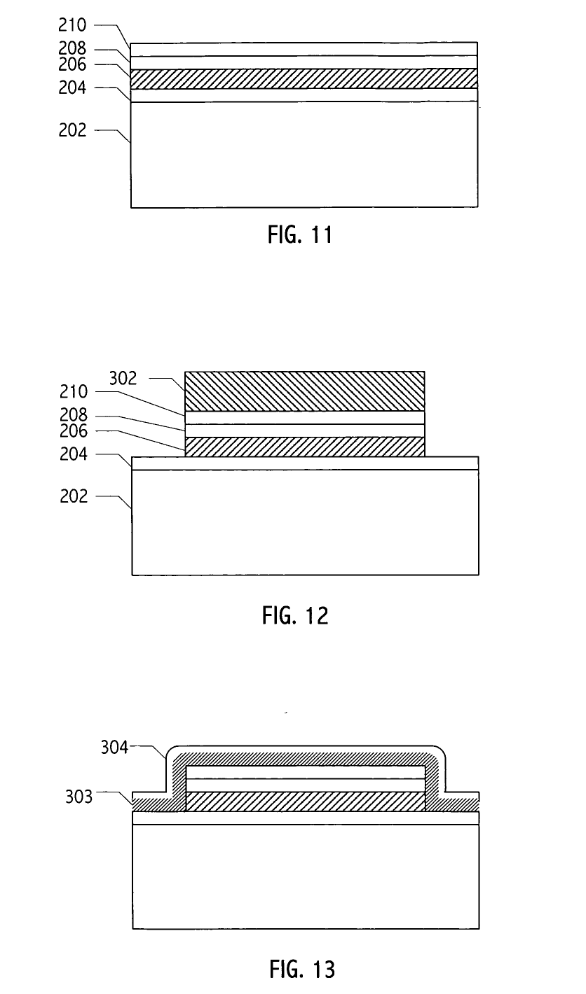

In some embodiments of the invention, a vertical thermoelectric device is manufactured consistent with the progressive stages of manufacture illustrated in FIGS. 11-20. Referring to FIG. 11, a dielectric layer (e.g., 100 nm SiO₂ dielectric layer 204) is formed on a substrate (e.g., substrate 202) as described above, with reference to FIG. 3. In some embodiments of the invention, dielectric layer 204 is patterned to form a conductive link, as described above. However, in some embodiments of the invention, conductive layers (e.g., conductive layers 206, 208, and 210) are formed, using techniques described above, on dielectric layer 204, as illustrated in FIG. 11. In an exemplary embodiment, conductive layer 206 is an approximately 800 nm thick aluminum material, conductive layer 208 is a 10 nm thick titanium-tungsten material, and conductive layer 210 is a 20 nm thick platinum material. However, other conductive structures with similar properties may be used. The conductive layers are patterned using a mask (e.g., mask 302) and semiconductor techniques (e.g., dry etch of conductive layers 208 and 210 and wet etch of conductive layer 206) to form the structure illustrated in FIG. 12.

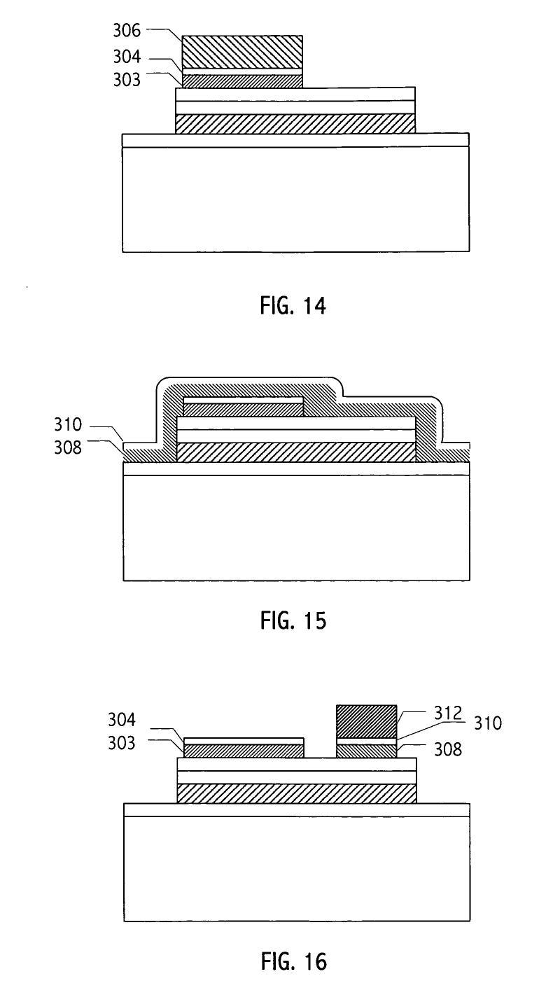

Referring to FIG. 13, mask 302 is removed and a p-type thermoelectric layer (e.g., thermoelectric material 303) is formed on the substrate as described previously. In an exemplary embodiment, thermoelectric material 303 is approximately 100 nm thick. Electrically conductive layer 304, is formed on the substrate. An exemplary electrically conductive layer 304 is an ultra-thin (approximately 10 nm) layer of platinum or other phonon conduction impeding material. Another mask, (e.g., photoresist mask 306) is formed on the substrate and thermoelectric material 303 and electrically conductive layer 304 are coarsely patterned (i.e., patterned to dimensions substantially greater than the final dimensions for the thermoelectric elements) and etched, using techniques described above and as shown in FIG. 14. Mask 306 may be removed after etch of electrically conductive layer 304 and electrically conductive layer 304 may be used as a mask for etching the remainder of the thermoelectric material 303 (e.g., using BCl₃).

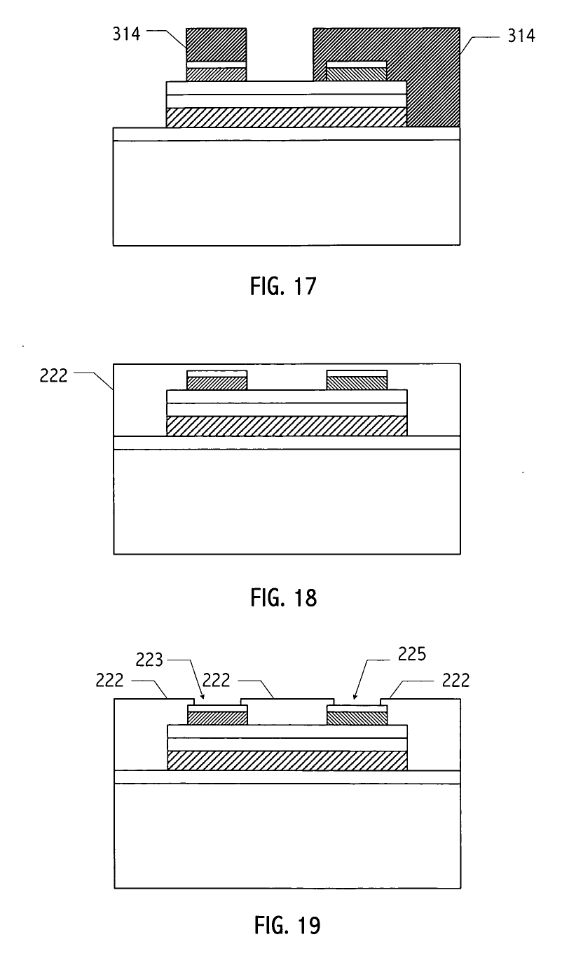

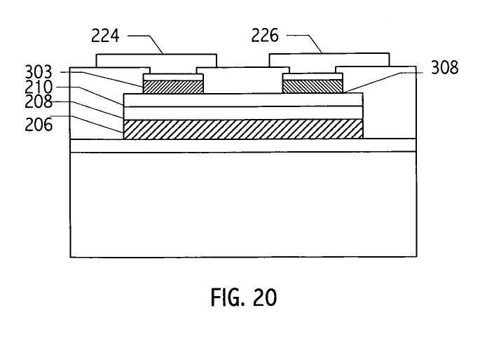

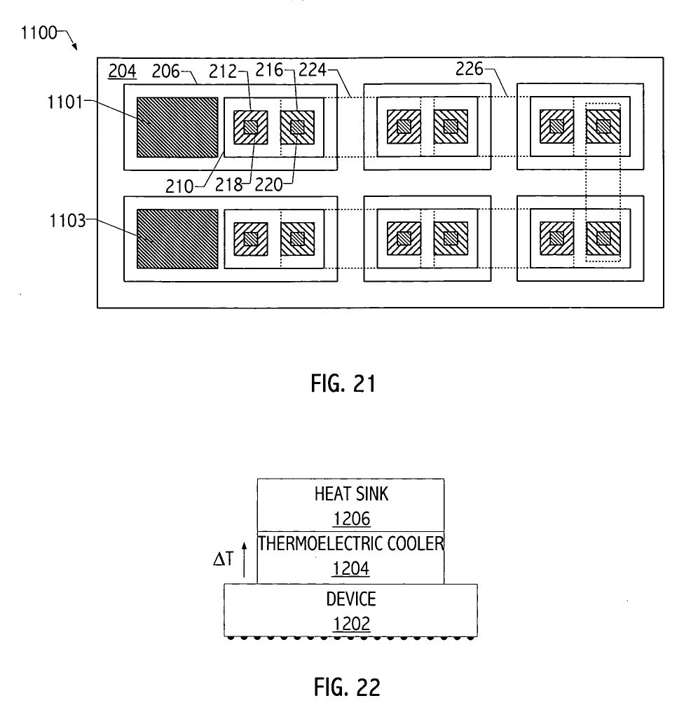

Referring to FIG. 15, an n-type thermoelectric layer (e.g., thermoelectric material 308) is formed on the substrate by techniques described previously. In an exemplary embodiment, thermoelectric material 308 is approximately 100 nm thick. Electrically conductive layer 310, is formed on the underlying structure. An exemplary electrically conductive layer 310 is an ultra-thin (approximately 10 nm) layer of platinum or other phonon conduction impeding material. Thermoelectric material 308 and electrically conductive layer 310 are finely patterned (i.e., patterned to approximately the final dimensions for the thermoelectric elements) using a mask (e.g., photoresist mask 312) as illustrated in FIG. 16. Mask 312 may be removed after etching conductive layer 310 and conductive layer 310 may then be used as a mask to etch the remaining thermoelectric material 308 (e.g., using BCl₃). Thermoelectric material 303 and electrically conductive layer 304 are then finely patterned using a mask (e.g., photoresist mask 314) as illustrated in FIG. 17. Mask 314 may be removed after etching conductive layer 304 and conductive layer 304 may then be used as a mask to etch the remaining thermoelectric material 303 (e.g., using BCl₃). The substrate may be annealed, followed by formation of an insulator 222 (FIG. 18), as described above (e.g., 500 nm SiO₂). Contact holes are formed in insulator 222 (FIG. 19) and contacts 224 and 226 (FIG. 20) are formed as described above.

In one embodiment thermoelectric element 303 is a p-type thermoelectric element and thermoelectric element 308 is n-type. Contact 224 is coupled to a positive potential, contact 226 is coupled to a negative potential, and conductive structures 206, 208, and 210 couple thermoelectric element 303 electrically in series with thermoelectric element 308, contacts 224 and 226 will have temperature T_{HOT}, and the conductive structure will have a temperature T_{COLD}, i.e., thermoelectric elements 303 and 308 are coupled electrically in series and thermally in parallel.

Multiple thermoelectric devices (e.g., thermoelectric device 101 of FIG. 1) formed monolithically on a substrate may be electrically coupled in a series configuration with a power source to provide thermal heat transfer for larger areas, and may be tailored to specific applications. Referring to FIG. 11, for example, a current may be generated in series configuration 1100 by applying a positive voltage to conductive link 206 at a bond pad opening (e.g., opening 1101) in a top dielectric (not shown) and a negative voltage at a bond pad opening (e.g., opening 1103) in the top dielectric. Referring to FIG. 22, in an exemplary application, thermoelectric cooler 1204 transfers heat from device 1202 to heat sink 1206. Thermoelectric cooler 1204 may be configured to provide localized cooling for hot spots of device 1202.

Various embodiments of techniques for implementing thermoelectric devices have been described. The description of the invention set forth herein is illustrative, and is not intended to limit the scope of the invention as set forth in the following claims. For example, although the present invention has been described primarily with reference to a thermoelectric cooling device, the invention may also be used as a power generator for generation of electricity. A thermoelectric device configured in the Peltier mode (as described above) may be used for refrigeration, while a thermoelectric device configured in the Seebeck mode may be used for electrical power generation. Other variations and modifications of the embodiments disclosed herein, may be made based on the description set forth herein, without departing from the scope of the invention as set forth in the following claims.

1. A thermoelectric device comprising a first thermoelectric material layer disposed between two electrodes, the first thermoelectric material layer having a thickness less than a thermalization length associated with the first thermoelectric material.

2. The thermoelectric device, as recited in claim 1, wherein the first thermoelectric material layer has a first conductivity type and is coupled electrically in series and thermally in parallel to a second thermoelectric material layer, the second thermoelectric material layer having a thickness less than a thermalization length associated with the second thermoelectric material and a conductivity type opposite the first conductivity type.

3. The thermoelectric device, as recited in claim 1, wherein the first thermoelectric material layer has a thickness less than approximately 20 μm.

4. The thermoelectric device, as recited in claim 1, wherein the first thermoelectric material layer has a thickness less than approximately 1 μm.

5. The thermoelectric device, as recited in claim 1, wherein the first thermoelectric material has a thermoelectric figure of merit (ZT) greater than approximately 1.

6. A monolithic thermoelectric device comprising:
a first electrode disposed above a substrate, the first electrode being thermally coupled to the substrate;
a first and a second thermoelectric element, each disposed above and coupled to the first electrode, the first thermoelectric element having a first conductivity type and the second thermoelectric element having a conductivity type opposite the first conductivity type;
a second electrode disposed above and coupled to the first thermoelectric element;
a third electrode disposed above and coupled to the second thermoelectric element;
wherein the first, second, and third electrodes couple the first and second thermoelectric elements electrically in series and thermally in parallel, and
wherein the first, second, and third electrodes comprise at least portions of monolithic layers.

7. The thermoelectric device, as recited in claim 6, wherein a thickness of at least one of the first and second thermoelectric elements is less than a thermalization length associated with the thermoelectric element.

8. The thermoelectric device, as recited in claim 6, further comprising:
an insulating film disposed between at least the first and the second electrodes in regions other than regions occupied by the first thermoelectric element.

9. The thermoelectric device, as recited in claim 8, wherein the insulating film comprises a polymer having a thermal conductivity less than approximately 0.1 W/m-K.

10. The thermoelectric device, as recited in claim 8, wherein the insulating film comprises a film having a dielectric constant less than approximately 3.9.

11. The thermoelectric device, as recited in claim 8, wherein the insulating film comprises a film having a dielectric constant less than approximately 2.

12. The thermoelectric device, as recited in claim 8, wherein the insulating film comprises an aerogel.

13. The thermoelectric device, as recited in claim 6, wherein the first electrode further comprises:
a first conductive layer thermally coupled to and electrically isolated from the substrate.

14. The thermoelectric device, as recited in claim 13, wherein the first electrode further comprises:
a second conductive layer between the first conductive layer and the thermoelectric elements, the second conductive layer for reducing diffusion between the first conductive layer and the thermoelectric elements.

15. The thermoelectric device, as recited in claim 14, wherein the first electrode further comprises:
a third conductive layer between the second conductive layer and the thermoelectric elements, the third conductive layer for increasing adhesion of the electrode to the thermoelectric elements.

16. The thermoelectric device, as recited in claim 6, wherein at least one of the electrodes further comprises:
an electrically conductive, phonon conduction impeding material at least in regions coupling the electrode to its associated thermoelectric element.

17. The thermoelectric device, as recited in claim 16, wherein the electrically conductive, phonon conduction impeding material comprises at least one of gallium, indium, lead, thallium, tin, lead-indium, lead-indium-tin, gallium-indium, gallium-indium-tin, gallium-indium with cesium doping at the surface, mercury, bismuth-tin, and bismuth-lead

18. The thermoelectric device, as recited in claim 6, wherein at least one of the second and third electrodes further comprises:
a first conductive layer electrically and thermally coupled to its associated thermoelectric element; and
a second conductive layer coupled to the first conductive layer and its associated thermoelectric element, the second conductive layer for reducing diffusion between the first conductive layer and its associated thermoelectric element.

19. The thermoelectric device, as recited in claim 6, wherein at least one of the first and second thermoelectric elements has a thickness less than approximately 20 μm.

20. The thermoelectric device, as recited in claim 6, wherein at least one of the first and second thermoelectric elements has a thickness less than approximately 1 μm.

21. The thermoelectric device, as recited in claim 6, wherein the thermoelectric elements have a thermoelectric figure of merit (ZT) greater than approximately 1.

22. A method for improving performance of a thermoelectric device comprising:
separating phonon transport from electron transport in at least one of a plurality of thermoelectric elements.

23. The method, as recited in claim 22, wherein the separating comprises providing a material in which electrons and phonons are not in thermal equilibrium at interfaces of the thermoelectric element to at least two associated electrodes.

24. The method, as recited in claim 22, further comprising:
reducing phonon thermal conductivity between at least one of the thermoelectric elements and a first electrode without significantly reducing electron thermal conductivity.

25. The method, as recited in claim 22, further comprising:
reducing from half of the Joule heat developed in at least one of the thermoelectric elements a backflow of Joule heat from the at least one of the thermoelectric elements into a corresponding electrode.

26. The method, as recited in claim 22, further comprising:
configuring electrically in series and thermally in parallel the plurality of thermoelectric elements, individual pairs of thermoelectric elements of the first type and opposing type being coupled to a respective electrode thermally coupled to a substrate;
generating a current through the plurality of thermoelectric elements to produce a temperature gradient across the thermoelectric device.

27. The method, as recited in claim 26, further comprising:
cooling another device by thermally coupling the thermoelectric device to the substrate.

28. The method, as recited in claim 26, further comprising:
transferring heat from the thermoelectric device to a heat sink.

29. A thermoelectric device comprising:
a first electrode disposed above a substrate of the thermoelectric device, the first electrode being thermally coupled to the substrate;
a second electrode disposed above the first electrode;
a third electrode disposed above the first electrode;
means for reducing phonon thermal conductivity between the first electrode and at least one of the second and third electrodes without significantly reducing electron thermal conductivity.

30. The apparatus, as recited in claim 29,
means for separating phonon transport from electron transport between the first electrode and the at least one of the second and third electrodes.
